(19) United States
(12) Patent Application Publication
(10) Pub. No.: US 2008/0160754 A1
(43) Pub. Date: Jul. 3, 2008

(54) METHOD FOR FABRICATING A MICROELECTRONIC CONDUCTOR STRUCTURE

(75) Inventors: John A. Fitzsimmons, Poughkeepsie, NY (US); Stephan Grunow, Wappingers Falls, NY (US); Sanjay C. Mehta, Schenectady, NY (US); Andrew H. Simon, Fishkill, NY (US); Chih-Chao Yang, Poughkeepsie, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/616,532

(22) Filed: Dec. 27, 2006

(51) Int. Cl. H01L 21/4763

(52) U.S. Cl. 438/626; 257/E21.495

(57) ABSTRACT

A method for fabricating a microelectronic structure includes forming a via aperture through a dielectric layer located over a substrate having a conductor layer therein, to expose the conductor layer. The conductor layer typically comprises a copper containing material. The method also includes etching the conductor layer to form a recessed conductor layer prior to etching a trench aperture within the dielectric layer. The trench aperture is typically contiguous with the via aperture to form a dual damascene aperture. By etching the conductor layer after forming the via aperture and before forming the trench aperture, such a dual damascene aperture is formed with enhanced dimensional integrity.

### BACKGROUND OF THE INVENTION

1. Field of the Invention

The invention relates generally to conductor structures within microelectronic structures. More particularly, the invention relates to methods for efficiently fabricating conductor structures within microelectronic structures.

2. Description of the Related Art

Microelectronic structures, such as semiconductor structures, often include resistors, transistors, capacitors and diodes that are connected and interconnected with conductor layers. The conductor layers contact the resistors, transistors, capacitors and diodes, as well as each other, at contact regions.

Within advanced semiconductor fabrication, conductor layers are often fabricated from copper containing conductor materials. In comparison with other conductor materials, copper containing conductor materials are desirable insofar as copper containing conductor materials generally provide enhanced electrical properties, such as enhanced electromigration resistance.

In addition, within advanced semiconductor fabrication copper containing conductor layers are often formed into dual damascene apertures within dielectric layers to provide contact to contact regions. Such dual damascene apertures include a via aperture portion contiguous with a trench aperture portion. The via aperture portion and the trench aperture portion may be filled simultaneously with a contiguous via and interconnect, layer which is also desirable for enhanced performance since such a configuration provides no interface or seam between a via and an interconnect within the contiguous via and interconnect layer.

Various conductor structures, and methods for fabrication thereof are known in the semiconductor fabrication art.

Specific examples of conductor structures are disclosed within: (1) Hashim et al., in U.S. Pat. Nos. 6,559,061, 6,709,987 & 6,992,012 (a copper containing conductor interconnect structure and a method for fabrication thereof that includes forming a barrier layer and/or an inter-level dielectric capping layer prior to contact layer sputtering to attenuate via-to-via leakage); (2) Karthikeyan et al., in U.S. Pat. No. 7,005,375 (another method for fabrication of a copper containing conductor interconnect structure that uses a barrier layer deposited prior to contact layer sputtering); (3) Wu et al., in U.S. Pat. No. 6,733,597 (a method for cleaning a dual damascene aperture that uses a chemical etchant followed by a plasma etchant.); (4) Chen et al., in U.S. Pat. No. 6,399,479 (an electroplating method for forming a conductor structure); and (5) Kita et al., in U.S. Pat. No. 5,254,363 (a method for forming an oxide layer that includes oxidation of a conductor metal layer).

Since conductor structures are important within semiconductor and other microelectronic structures for adequate performance, desirable are conductor structures, and methods for fabrication thereof, that provide for enhanced performance of semiconductor and other microelectronic structures.

### SUMMARY OF THE INVENTION

The invention provides a method for fabricating a microelectronic structure that includes a conductor structure. The conductor structure may include a dual damascene structure. The particular method is a via aperture first method that provides for selectively removing material from a conductor layer at the base of a via aperture through a dielectric layer to form a non-isotropic recess into the conductor layer. Typical, techniques used to create this non-isotropic recess into the conductor layer include sputtering techniques utilizing a directional beam of chemically inert ions such as but not limited to Ar, Kr and Xe ions. Reactive ion etch (RIE) techniques utilizing a directional beam of chemically reactive ions such as but not limited to F, Cl, Br, I, BCl₃, NO and HCCL₃ derived ions, and directional ion cluster beams utilizing ion clusters of similar and dissimilar ions such as NO, NO₂, OF and OCl derived ions, may also be used. A key requirement during the selection of chemistries utilized for the creation of this non-isotropic recess is that residues are not left after the completion of this non-isotropic recess that would promote a time delayed corrosion effect on a conductor material from which is comprised the conductor layer.

This process creates a recess into a conductor layer that is, for example, not necessarily exclusively a copper containing conductor layer at the base of a via aperture through a dielectric layer prior to forming a trench aperture that is typically contiguous with the via aperture within the dielectric layer. The method provides an advantage in the ordering of: (1) via aperture formation first; (2) conductor layer recess creation; and then (3) trench aperture formation, since all portions of the dielectric layer may be covered by a hard mask layer when creating the recess into the conductor layer. When the dielectric layer is not covered by such a hard mask layer, portions of the dielectric layer may also be etched when the recess is formed into the conductor layer.

A method in accordance with the invention includes forming through a dielectric layer over a substrate that includes a conductor layer a via aperture to expose the conductor layer. The method also includes removing a portion of the conductor layer at the base of the via aperture to form a recessed conductor layer. The method finally also includes forming a trench aperture within the dielectric layer.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, that form a material part of this disclosure, wherein:

FIG. 1 to FIG. 8 show a series of schematic cross-sectional diagrams illustrating the results of progressive stages in fabricating a microelectronic structure in accordance with an embodiment of the invention.

### DESCRIPTION OF THE PREFERRED EMBODIMENT

The invention, which includes a method for fabricating a conductor structure, is understood within the context of the description provided below. The description provided below is understood within the context of the drawings described above. Since the drawings are intended for illustrative purposes, the drawings are not necessarily drawn to scale.

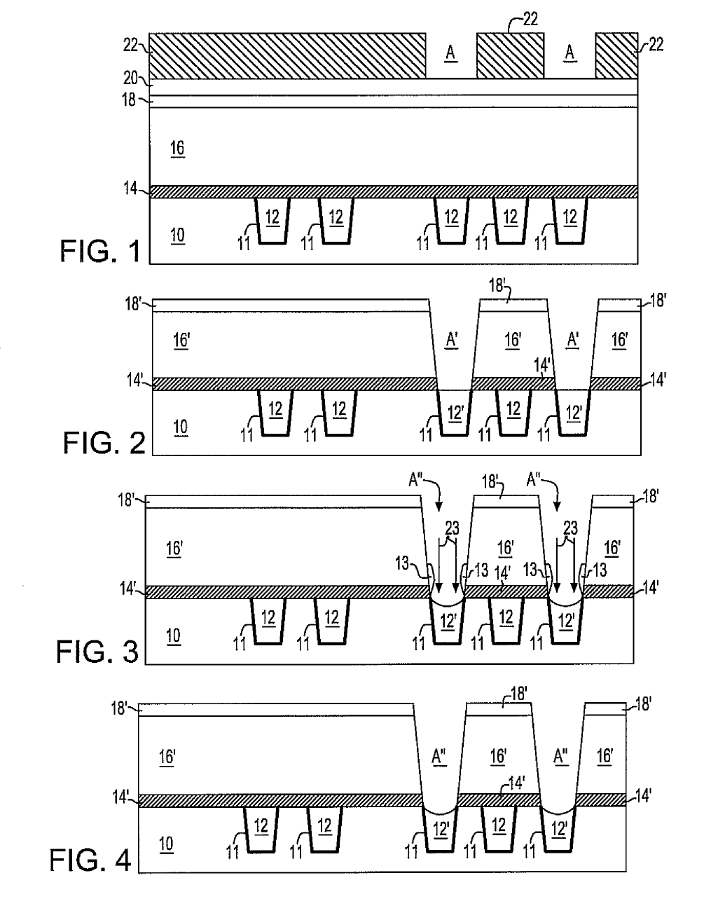

FIG. 1 to FIG. 8 show a series of schematic cross-sectional diagrams illustrating the results of progressive stages of fabricating a conductor structure including a dual damascene aperture in accordance with an embodiment of the invention.

FIG. 1 shows a substrate 10. Embedded within the substrate 10 is a plurality of first conductor layers 12 each of which is separated from the substrate 10 by a first liner layer 11. A first capping layer 14 is located capping exposed portions of the substrate 10, the first liner layers 11 and the first conductor layers 12.

FIG. 1 also shows, in further succession: (1) an inter-level dielectric layer 16 located upon the first capping layer 14; (2) a first hard mask layer 18 located upon the inter-level dielectric layer 16; (3) a first anti-reflective coating (ARC) layer 20 located upon the first hard mask layer 18; and (4) a first photoresist layer 22 located upon the first anti-reflective coating (ARC) layer 20.

Each of the foregoing substrate 10 and layers 11, 12, 14, 16, 18, 20 and 22 may comprise materials, have dimensions and be formed using methods that are otherwise generally conventional in the semiconductor fabrication art.

For example, the substrate 10 may comprise materials including but not limited to conductor materials, semiconductor materials and dielectric materials. Typically, the substrate 10 will include a semiconductor material in the form of a semiconductor substrate, but neither the embodiment nor the invention is so limited to a semiconductor substrate. Typical examples of semiconductor materials from which may be comprised the substrate 10 include but are not limited to silicon, germanium, silicon-germanium alloy, silicon carbide, silicon-germanium carbide alloy and compound semiconductor materials. Non-limiting examples of compound semiconductor materials include gallium arsenide, indium arsenide and indium phosphide semiconductor materials.

The liner layers 11 typically comprise conductor liner materials, although other liner materials, such as dielectric liner materials, are not excluded. Particular non-limiting examples of conductor liner materials include pure, alloyed or nitrided compounds of titanium, tungsten, tantalum and ruthenium that may be formed using methods including but not limited to thermal or plasma nitridation methods, chemical vapor deposition methods, atomic layer deposition methods and physical vapor deposition methods. Typically, each of the liner layers 11 has a thickness from about 10 to about 500 angstroms.

Tie first conductor layers 12 are not limited to, but typically can comprise copper, aluminum, gold, silver, chrome, tungsten, or other alloys or conducting metals as conductor materials. For example, in the case of copper containing conductor materials the first conductor layers 12 may include pure copper, as well as copper alloys with other conductor materials such as but not limited to tantalum, titanium and aluminum conductor materials. Conductor materials in general may be formed using methods including but not limited to plating methods, chemical vapor deposition methods and physical vapor deposition methods. Typically, each of the first conductor layers 12 is embedded to a depth from about 300 to about 5000 angstroms within the substrate 10, while having a linewidth from about 0.055 to about 0.18 microns within the substrate 10.

The first capping layer 14 is typically intended as comprising a dielectric capping material. Dielectric capping materials may include, but are not limited to oxides, nitrides, carbonitrides and oxynitrides of silicon, although oxides, nitrides and oxynitrides of other elements are not excluded. Also not excluded are, silicon oxycarbonitrides, silicon oxycarbides, boronitrides, borocarbides, borocarbonitrides. Silicon nitride and silicon carbonitride capping materials are generally particularly common. The foregoing dielectric capping materials may be formed using methods including but not limited to thermal or plasma oxidation or nitridation methods, chemical vapor deposition methods and physical vapor deposition methods. Typically, the first capping layer 14 comprises a nitrogenated dielectric material that has a thickness from about 100 to about 1000 angstroms.

The inter-level dielectric layer 16 also comprises a dielectric material. However, the dielectric material from which is comprised the inter-level dielectric layer 16 is generally a less dense dielectric material that will typically have a lower dielectric constant than a generally conventional silicon oxide, silicon nitride or a silicon oxynitride dielectric material (i.e., that has a lower dielectric constant in a range from about 1.7 to about 3.7). Porous dielectric materials may include, but are not limited to, porous silicate glasses, silicon oxycarbides, silicon oxycarbofluorides, aerogels and hydrogels, as well as other low dielectric constant dielectric materials. Such porous dielectric materials may be formed using methods including but not limited to spin-on methods, chemical vapor deposition methods and physical vapor deposition methods. Typically, the inter-level dielectric (ILD) layer 16 has a thickness from about 2000 to about 8000 angstroms.

The first hard mask layer 18 comprises a hard mask material. Non-limiting examples of hard mask materials include silicon nitride, silicon oxide, silicon oxynitride, silicon carbonitride, silicon oxycarbonitride, silicon oxycarbofluoride, silicon oxycarbide, boronitride, borocarbide and borocarbonitride hard mask materials which may be formed using methods analogous, equivalent or identical to the methods that are used for forming the first capping layer 14. Typically, the first hard mask layer 18 comprises a silicon oxide material that has a thickness from about 200 to about 1000 angstroms.

The first anti-reflective coating (ARC) layer 20 comprises an anti-reflective coating (ARC) material. Anti-reflective coating (ARC) materials include inorganic anti-reflective coating materials and organic anti-reflective coating materials, as well as composite anti-reflective coating materials thereof. Organic anti-reflective coating materials are more common, and they typically comprise organic polymer materials that include dyes. Typically, the first anti-reflective coating (ARC) layer 20 has a thickness from about 500 to about 5000 angstroms.

The first photoresist layer 22 comprises a photoresist material. Non-limiting examples of photoresist materials include positive photoresist materials, negative photoresist materials and hybrid photoresist materials. Typically, the first photoresist layer 22 comprises a positive photoresist material or a negative photoresist material that has a thickness from about 1000 to about 5000 angstroms. The first photoresist layer 22 further defines a plurality of apertures A nominally centered above separated ones of the first conductor layers 12.

FIG. 2 first shows the results of sequentially etching the first anti-reflective coating (ARC) layer 20, the first hard mask layer 18, the inter-level dielectric layer 16 and the first capping layer 14, while using the first photoresist layer 22 as a mask, to expose two of the first copper containing conductor layers 12. FIG. 2 also shows the results of stripping the first photoresist layer 22 and a first antireflective coating (ARC) layer that results from etching of the first anti-reflective coating (ARC) layer 20, to leave remaining a first hard mask layer 18′, an inter-level dielectric layer 16′ and a first capping layer 14′ that define a plurality of corresponding apertures A′ that expose two of the conductor layers 12.

The foregoing etching is undertaken using methods and materials that are otherwise generally conventional in the semiconductor fabrication art. Such methods typically include dry plasma etch methods since such dry plasma etch methods typically provide nominally straight sidewalls to the foregoing patterned layers. Fluorine containing etchant gas compositions are typically used when etching silicon containing dielectric materials.

The foregoing stripping of the first photoresist layer 22 and remaining portions of the anti-reflective coating (ARC) layer 18 may be effected using methods including but not limited to wet chemical etch methods and dry plasma etch methods.

FIG. 3 shows the results of ion sputtering exposed portions of the plurality of first conductor layers 12 to form a plurality of first conductor layers 12′ that are dished (i.e., recessed) with respect to first conductor layers 12. Also formed are residue layers 13 at the sidewalls of a plurality of apertures A″ that derive from the plurality of apertures A′. The ion sputtering uses argon sputtering ions 23, although other sputtering ions as noted in the Summary are not excluded. As also noted above within the Summary, alternative directional chemical etchants are also not excluded. The argon sputtering ions 23 are provided at: (1) an argon flow rate from about 5 to about 200 standard cubic centimeters per minute; (2) a bias power from about 250 to about 5000 watts; and (3) a sputtering time from about 1 to about 60 seconds. The ion sputtering leaves no residue that yields a time delayed corrosion of the first conductor layers 12′.

As is illustrated within the schematic cross-sectional diagram of FIG. 3, due to the presence of the first hard mask layer 18′ covering all portions of the inter-level dielectric (ED) layer 16′, no portions of the inter-level dielectric layer 16′ sustain sputter etching damage when sputter etching the first conductor layers 12 to form the first conductor layers 12′.

FIG. 4 shows the results of removing the residue layer 13 and any damaged portions (i.e., potentially carbon dopant depleted) of the inter-level dielectric (ILD) layer 16 from the sides of the apertures A″. Within the context of the instant embodiment, the residue layers 13 are removed using a two step method. A first step within the two step method provides for oxidation of the residue layers 13 to provide oxidized residue layers. The oxidized residue layers may subsequently be stripped using dilute organic or inorganic acids such as, but not limited to, oxalic acid, acetic acid and hydrofluoric acid etching solutions when the oxidized residue layers comprise a copper oxide residue material. The oxidized residue layers are oxidized using an oxygen plasma that is provided at an oxygen flow rate from about 5 to about 100 standard cubic centimeters per minute and a plasma power from about 100 to about 500 watts, for a treatment time from about 5 to about 50 seconds. The oxidized residue layers are stripped using a 0.001% to 1% v/v dilute aqueous hydrofluoric acid solution at a temperature from about 15 C to about 35 C.

Alternatively, the residue layers 13 with or without damaged portions of the inter-level dielectric layer 16 may be removed using other etchant solutions that provide for less critical dimension (CD) loss of the inter-level dielectric (ILD) layer 16 material.

Within the context of such an alternative method, an etchant that is non-oxidizing to the inter-level dielectric (ILD) layer 16 (but may be oxidizing to trace metals) is used to remove the residue layers 13. Typical materials that may be used for this etchant are not generally known to oxidize trace metals, but are used to remove photoresist and post RIE residues. Specific examples include solvent or semi-aqueous chemistries such as: (1) ST-250 from ATMI; (2) NE-14, NE-111 from Air Products; and (3) AZ 400T from Clariant Corporation. Other similar formulations may also be used. The oxidation of trace metals may be accomplished with any of the foregoing etchants by the addition of a slightly oxidizing source, such as oxygen in a range from about 1 to about 10,000 ppm, to any of the foregoing etchants.

Alternatively, a separate step may be used to oxidize trace metals. Such a separate step may use an aqueous, semi-aqueous, or non-aqueous solution of a slightly oxidizing source, such as oxygen in a range from about 1 to about 10,000 ppm.

An additional etch step may also be used to fully remove any trace metal or oxidized trace metal remaining after the above etch steps. This additional metal or metal oxide removal may be accomplished using dilute organic or inorganic acids such as, but not limited to, oxalic acid, acetic acid and hydrofluoric acid etching solutions when the oxidized residue layers comprise a copper oxide residue material. A typical condition that may be used to remove a copper oxide residue and not attack a damaged inter-level dielectric (ILD) layer 16 is an aqueous acetic acid solution in a range from about 0.01 to about 1 volume percent at a temperature from about 15 C to about 35 C. However, other chemistries based on weak acid solutions or ultra dilute fluoride (i.e., on the order of about 1000:1 v/v deionized water:HF) may also be used.

This embodiment does not preclude alternative methods for removing tie residue layers 13.

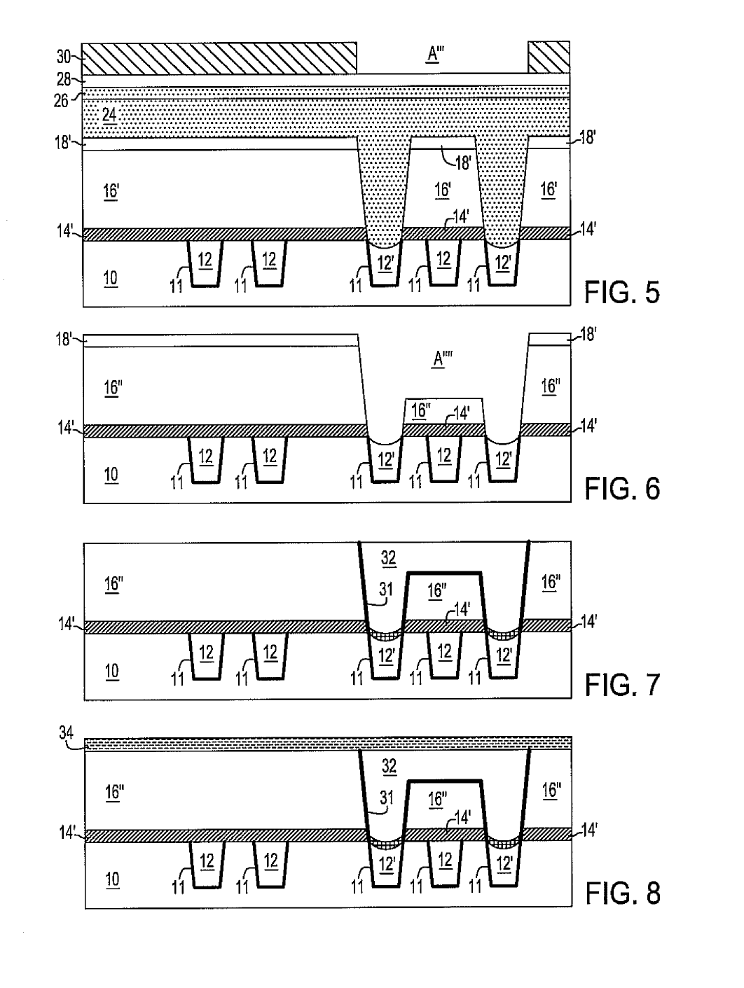

FIG. 5 first shows a planarizing layer 24 located upon the semiconductor structure of FIG. 4. A second bard mask layer 26 is located upon the planarizing layer 24. A second anti-reflective coating (ARC) layer 28 is located upon the upon the second hard mask layer 26. Finally, a second photoresist layer 30 is located upon the second anti-reflective coating (ARC) layer 28.

The planarizing layer 24 comprises a planarizing material. The planarizing material is typically an organic polymer planarizing material. Typically, the organic polymer planarizing material is formed to a thickness from about 1000 to about 5000 angstroms while typically using a spin-coating method. Other planarizing methods and planarizing materials are not excluded.

The second hard mask layer 26, the second anti-reflective coating layer 28 and the second photoresist layer 30 are otherwise analogous to the first hard mask layer 18, first anti-reflective coating layer 20 and first photoresist layer 22 that are illustrated in FIG. 1, but with the exception that the second photoresist layer 30 defines an aperture A′″ intended to encompass the locations of the apertures A″ that are illustrated in FIG. 4.

FIG. 6 shows the results of patterning the inter-level dielectric layer 16′ to form an inter-level dielectric layer 16″ while using the second photoresist layer 30 as an etch mask layer. The inter-level dielectric layer 16″ and a second hard mask layer 18′ that results from patterning of the second hard mask layer 18 provide an aperture A″″ from the aperture A′″. The foregoing etching that provides the aperture A″″ is analogous to the etching of the aperture A within FIG. 1 to provide the aperture A′ that is illustrated in FIG. 2. Subsequent to etching the dielectric layer 16′ to provide the dielectric layer 16″ that defines the aperture A″″, the second photoresist layer 30 and remaining portions of the second anti-reflective coating layer 28, the second hard mask layer 26 and the planarizing layer 24 are stripped. Such stripping may use methods and materials that are conventional in the art, as noted above within the context of FIG. 2.

Since within the instantly described embodiment argon (or another sputtering ion) is used to sputter the conductor layers 12′ within the via apertures A″ that are illustrated in FIG. 3 prior to forming the contiguous via and trench aperture A″″ that is illustrated in FIG. 6 (i.e., a dual damascene aperture), a remaining portion of the inter-level dielectric layer 16″ within the via and trench aperture A″″ is not exposed to a sputter etchant (i.e., the location of the remaining portion of the inter-level dielectric layer 16″ is covered by a portion of the first hard mask layer 18′). This remaining portion of the inter-level dielectric layer 16″ thus does not erode and is not otherwise mechanically or dimensionally compromised.

FIG. 7 shows a second liner layer 31 located conformally covering the contiguous via and trench aperture A″″ that is illustrated in FIG. 6. FIG. 7 also shows a second copper containing conductor layer 32 (i.e., a via and interconnect layer) located upon the first liner layer 31 and completely filling the contiguous via and trench aperture A″″.

The first liner layer 31 may comprise liner materials, have dimensions and be formed using methods that are analogous, equivalent or identical to the materials, dimensions and methods that are used for forming the first liner layers 11. The second conductor layer 32 is otherwise analogous, equivalent or identical to the first conductor layers 12 that are illustrated in FIG. 1.

FIG. 8 shows a second capping layer 34 located upon the semiconductor structure of FIG. 7. The second capping layer 34 may comprise materials, have dimensions and be formed using methods analogous, equivalent or identical to those used within the context of the first capping layer 14′.

FIG. 8 shows a schematic cross-sectional diagram of a microelectronic structure in accordance with a particular embodiment of the invention. The microelectronic structure includes a first conductor layer 12′ at the bottom of a via aperture within a dual damascene aperture. The first conductor layer 12′ is recessed by virtue of treatment with a sputtering ion that typically includes an argon sputtering ion. The conductor layer 12′ is recessed due to treatment with the sputtering ion absent undesirable etching of other portions of the dual damascene aperture (i.e., portions of an inter-level dielectric layer 16″ that comprises the dual damascene aperture) by treatment with the argon sputtering ion. The foregoing result is realized by argon sputter etching the conductor layers 12′ after forming a via aperture to expose unsputtered conductor layers 12, but prior to forming a trench aperture that enlarges the via aperture to form the dual damascene aperture.

The preferred embodiment is illustrative of the invention rather than limiting of the invention. Revisions and modifications may be made to methods, materials, structures and dimensions of a microelectronic structure in accordance with the preferred embodiment, while still providing microelectronic structure in accordance with the invention, further in accordance with the accompanying claims.

What is claimed is:

1. A method for fabricating a microelectronic structure comprising:
forming through a dielectric layer over a substrate that includes a conductor layer a via aperture to expose the conductor layer;
removing a portion of the conductor layer at the base of the via aperture to form a recessed conductor layer; and then
forming a trench aperture within the dielectric layer.

2. The method of claim 1 wherein the forming the trench aperture within the dielectric layer forms the trench aperture contiguous with the via aperture to provide a dual damascene aperture.

3. The method of claim 1 wherein the forming the via aperture through the dielectric layer further includes forming the via aperture through a hard mask layer formed upon the dielectric layer.

4. The method of claim 3 wherein a sputtering of the dielectric layer is inhibited by the hard mask layer.

5. The method of claim 2 further comprising conformally forming a liner layer into the dual damascene aperture.

6. The method of claim 5 further comprising forming an additional conductor layer into the dual damascene aperture and upon the liner layer.

7. The method of claim 6 wherein the each of the conductor layer and the additional conductor layer comprises a copper containing conductor material.
